(19) United States
(12) Patent Application Publication
(10) Pub. No.: US 2025/0114819 A1
(43) Pub. Date: Apr. 10, 2025

(54) RESISTANT COATINGS INCLUDING POLYMER SEALANT AND RESISTANT PARTICLES

(71) Applicant: Applied Materials, Inc., Santa Clara, CA (US)

(72) Inventor: George Ea-Hwan Kim, Cupertino, CA (US)

(21) Appl. No.: 18/484,352

(22) Filed: Oct. 10, 2023

(51) Int. Cl. B05D 1/00; C09D 7/40; C09D 7/61

(52) U.S. Cl. CPC B05D 1/60; C09D 7/61; C09D 7/66; B05D 2203/30; B05D 2259/00; B05D 2601/00

(57) ABSTRACT

A component includes a body and a coating deposited on a surface of the body. The coating includes a porous ceramic. The coating further includes a polymer sealant. The coating further includes a plurality of particles disposed within the polymer sealant.

### TECHNICAL FIELD

Embodiments of the present disclosure relate to resistant coatings. Specifically, embodiments of the present disclosure relate to resistant coatings that include polymer sealant and resistant particles.

### BACKGROUND

Chambers are used in many types of processing systems. Examples of chambers include etch chambers, deposition chambers, anneal chambers, metrology chambers, and the like. Typically, a substrate, such as a semiconductor wafer, is placed on a substrate support within the chamber and operations are performed to advance processing of the substrate. Processing the substrate may include exposing the substrate to a corrosive environment. Various components of a process chamber, process system, manufacturing system, or the like may also be exposed to the corrosive environment. Providing a coating for one or more components may protect the components from damage due to the corrosive environment.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In some aspects of the present disclosure, a component includes a body and a coating deposited on a surface of the body. The coating includes a porous ceramic. The coating further includes a polymer sealant. The coating further includes a plurality of particles disposed within the polymer sealant.

In some aspects of the present disclosure, a method includes forming a porous ceramic coating on a first surface of a body. The method further includes disposing a polymer sealant precursor comprising a plurality of particles within one or more pores of the porous ceramic coating. The method further includes curing the polymer sealant precursor to generate a polymer sealant.

In some aspects of the present disclosure, a substrate processing chamber includes a component. The component includes a metal body. The component further includes a coating deposited on a surface of the metal body. The coating includes a porous ceramic. The coating further includes a polymer sealant. The coating further includes a plurality of particles disposed within the polymer sealant.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a top schematic view of an example processing system, according to some embodiments.

FIG. 2 is a sectional view of a processing chamber having one or more chamber components that may be coating with a resistant coating, according to some embodiments.

FIG. 3A illustrates a coated article having a body and a coating, according to some embodiments.

FIG. 3B depicts a coated article including a body and a number of coating layers, according to some embodiments.

FIG. 4 illustrates an example architecture of a deposition system for performing aerosol or thermal spray deposition, according to some embodiments.

FIG. 5 depicts an apparatus for performing plasma electrolytic oxidation (PEO), according to some embodiments.

FIGS. 6A-B depict a mechanism and apparatus for performing deposition techniques utilizing energetic particles, according to some embodiments.

FIG. 7 depicts a schematic drawing of a plasma spray deposition apparatus used for spray deposition techniques, according to some embodiments.

FIG. 8 is a flow diagram of a method for generating a coating including a polymer sealant and resistant particles, according to some embodiments.

### DETAILED DESCRIPTION OF EMBODIMENTS

Described herein are methods, systems, devices, etc., related to providing a resistant coating for components of a manufacturing system, such as a substrate manufacturing system, semiconductor wafer manufacturing equipment, or the like. The resistant coating described herein may include a porous coating layer, such as a ceramic layer that includes features providing access for molecules to migrate to regions within the resistant coating. The resistant coating described herein may include a sealant, disposed within the pores of the porous coating layer. The resistant coating described herein may further include resistant particles disposed within the sealant in the pores of the porous coating layer.

Substrates are processed and/or manufactured in one or more processing chambers. Processing chambers may distinguish and separate the processing environment (e.g., the region of space in which substrates are processed) from ambient conditions. For example, substrate processing may be performed at a controlled gas pressure, under a controlled gas mixture, under vacuum, etc. Substrates may be processed to fulfill target conditions, target performance metrics, target substrate properties, etc.

Substrate processing may include exposing the substrate to a corrosive environment, such as a plasma environment, a dry etch environment, a chemical etch environment, or the like. One or more components of a substrate processing chamber may also be exposed to the corrosive environment. Components of a substrate processing chamber may be composed of materials that are vulnerable to various corrosive environments used in substrate processing. One or more coatings may be applied to components of the process chamber, e.g., coatings that are resistant to corrosive environments to be generated in the process chamber. Coatings may be ceramic, metal oxide, or another material resistant to the corrosive environments the component is to be exposed to.

Protective coatings may be applied using a variety of deposition methods. Some methods may generate coatings that are not of uniform thickness, not of uniform quality, porous, or the like. “Porous,” as used herein, indicates that a substance, material, coating, component, of the like includes channels, shafts, cracks, gaps, or other imperfections that enable a fluid to penetrate beyond the outer surface, potentially to a deeper component beneath the porous layer. In some cases, further coating operations may be performed to provide protection to material exposed by the porous nature of the coating. For example, layers of coating may be applied using a different deposition method, a different material may be applied, or a sealant may be applied that infiltrates pores of the coating.

In some systems, a coating method may be utilized that generates a coating that is not porous. For example, atomic layer deposition (ALD) may generate a coating that is not porous and is not dependent on line-of-sight deposition. However, such techniques have other shortcomings. Cost of performing techniques to generate non-porous coatings may be high. For example, coating by ALD may include hours or days of coating operations to generate a thin layer of coating material. Methods that generate a porous coating may have qualities such as relative ease, low cost, thickness and robustness of coatings generated, compared to techniques such as ALD.

Utilizing a second coating material to compensate for coating porosity has shortcomings. In some cases, a second coating material may be selected for the ability of the second material to infiltrate the pores of the porous coating material, and the material properties of the second coating material may not be as well suited to corrosion resistance as the first coating material. Choice of second material may be constrained by coverage ability, strength of an interface with the porous coating material, mechanical integrity, and other factors which may cause selection of a material that is not as resistant to corrosion as the first material, a material that may corrupt a processing environment or substrate, a component that ages or changes upon exposure to corrosive environments, etc.

Systems and methods of the present disclosure may address one or more shortcomings of conventional systems. In some embodiments, a protective coating is applied to a body. The body may be metal, e.g., aluminum. The body may be a component of a process chamber, such as a chamber liner, plasma screen, cathode sleeve, or another components of a process chamber. The protective coating may be applied by a variety of methods, such as physical vapor deposition (PVD), plasma electrolytic oxidation (PEO), thermal spraying, plasma spraying, chemical vapor deposition, or another coating application method. The protective coating may be a metal oxide, a ceramic material, or another resistive coating material. The protective coating may be porous (e.g., include channels, cracks, gaps, or the like).

In some embodiments, a polymer sealant precursor is applied to the porous coating. The polymer sealant precursor may be disposed into pores of the protective coating. The polymer sealant precursor may cure into a polymer sealant. The polymer sealant may permeate the surface of the porous coating to a depth of about 50 μm, to a depth between 10 μm and 500 μm, or the like. The polymer sealant precursor may be selected to cure into a polymer sealant under ambient (e.g., atmospheric) conditions. The polymer sealant may cure upon mixing with a mixing agent, application of heat, alteration of pressure, or another curing method. The polymer sealant precursor may include particles of a resistant material, e.g., a corrosion resistant material. The particles may be nanoparticles of resistant material, e.g., between 10 nm and 500 nm in diameter. The particles may be of a ceramic material, a metal oxide material, or the like. The particles may be of yttrium oxyfluoride, yttrium fluoride, aluminum oxide, yttrium oxide, magnesium oxide, or another resistant material. The particles may be included in the sealant precursor, and may be included in the polymer sealant once the polymer sealant precursor is cured. The particles may impart additional corrosive environment resistance to the polymer sealant (e.g., the sealant with the particles may be more resistant to corrosive environments than the same sealant without the resistant particles). In some embodiments, polymer sealant precursor may be applied in multiple operations (which may or may not include curing operations between the applications). Different properties of polymer sealant precursor may be selected for different application of precursor. For example, a first application may include a low concentration of resistant particles (or no particles), a second application may include a higher concentration of resistant particles, a third application may include a still higher concentration of resistant particles, etc. In some embodiments, a polymer sealant precursor may be applied to the porous coating, and subsequent to applying the polymer sealant precursor, a plurality of resistant particles may be applied to the polymer sealant precursor.

Methods and systems of the present disclosure provide technological advantages over conventional methods. Coating operations may be utilized in accordance with the present disclosure that include less investment in terms of coating time, coating expense, coating equipment, reagent expense, etc., compared to other coating methods. Convenient coating methods may be utilized to generate a coated article. Application of a polymer sealant impregnated with resistive particles (e.g., ceramic nanoparticles) may improve the protection to the a coated component compared to an unsealed coating. Inclusion of resistant particles in the polymer sealant may improve resistance of the sealant, reduce frequency and/or severity of polymer sealant breakdown, reduce frequency and/or severity of contamination of a substrate or the substrate processing chamber due to sealant failure, etc.

In some aspects of the present disclosure, a component includes a body and a coating deposited on a surface of the body. The coating includes a porous ceramic. The coating further includes a polymer sealant. The coating further includes a plurality of particles disposed within the polymer sealant.

In some aspects of the present disclosure, a method includes forming a porous ceramic coating on a first surface of a body. The method further includes disposing a polymer sealant precursor comprising a plurality of particles within one or more pores of the porous ceramic coating. The method further includes curing the polymer sealant precursor to generate a polymer sealant.

In some aspects of the present disclosure, a substrate processing chamber includes a component. The component includes a metal body. The component further includes a coating deposited on a surface of the metal body. The coating includes a porous ceramic. The coating further includes a polymer sealant. The coating further includes a plurality of particles disposed within the polymer sealant.

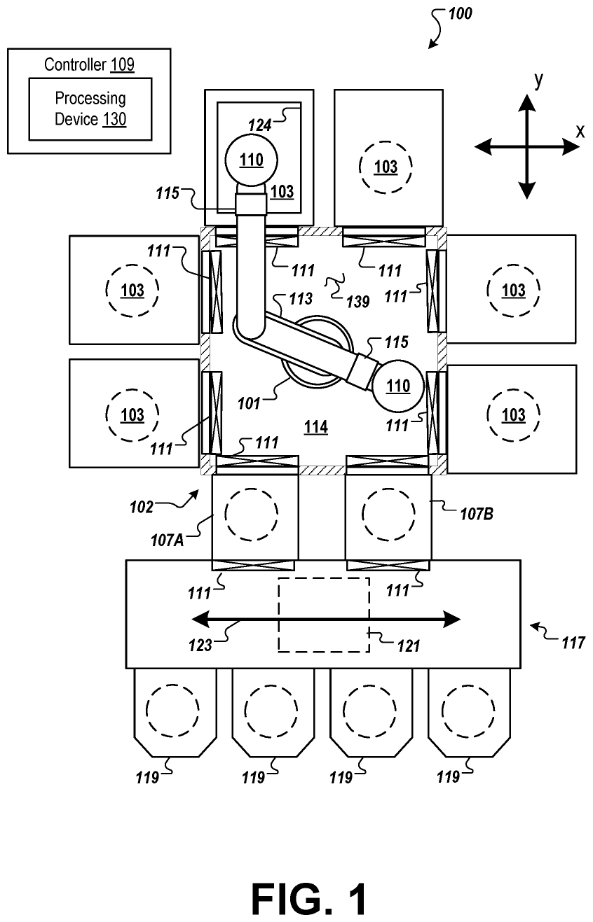

FIG. 1 is a top schematic view of an example processing system 100, according to some embodiments. Processing system 100 may be a substrate processing system. Processing system 100 includes a substrate processing apparatus (e.g., substrate processing tool, physical components for substrate processing operations) and one or more computing devices (e.g., processing devices). Processing system 100 includes a transfer chamber robot 101 and a factory interface robot 121 each adapted to pick and place substrates 110 (sometimes referred to as “wafers” or “semiconductor wafers”) from or to a destination in an electronic device processing system such as the processing system 100 illustrated in FIG. 1. However, any type of electronic device substrate, mask, or other silica-containing substrate (generally referred to as “substrates” herein) may be conveyed and transferred by the disclosed robots. For example, the destination for the substrates 110 may be one or more chambers 103 and/or one or more of the load lock apparatus 107A, 107B that may be distributed about and coupled to a transfer chamber 114. As shown, substrate transfers may be through slit valves 111, for example. Chambers 103 may include process chambers, metrology chambers, lithography chambers, anneal chambers, deposition chambers, etch chambers, etc.

Processing system 100 may further include a mainframe 102 including the transfer chamber 114 and a number of chambers 103. A housing of the mainframe 102 includes the transfer chamber 114 therein. The transfer chamber 114 may include top wall (not shown), bottom wall (floor) 139, and side walls, and may include a controlled environment. The controlled environment may include vacuum conditions, a controlled pressure (e.g., different from ambient atmospheric pressure), a controlled gas environment (e.g., inert gas such as argon or nitrogen gas or a gas mix), or the like. In the depicted embodiment, the transfer chamber robot 101 is mounted to the bottom wall (floor) 139. However, the transfer chamber robot 101 could be mounted elsewhere, such as to the top wall.

In various embodiments, chambers 103 may be adapted to carry out any number of processes on substrates 110. The processes may include deposition, oxidation, nitration, etching, polishing, cleaning, lithography, metrology (e.g., integrated metrology), or the like. Chambers 103 may include components for performing intended functions of the chambers 103, for providing protection to other components of chambers 103, etc. For example, chambers may include chamber liners 124, plasma screens, cathode sleeves, showerheads, etc., for handling process gas, protecting mainframe 102 from corrosive gas environments used to process substrates, and other functions. Any combination of chambers 103 may include one or more liner components, with chamber liner 124 being shown and others omitted from FIG. 1 for clarity. Any component of processing system 100 that may benefit from protection from corrosive environments may be provided with a coating including a polymer sealant with resistant particles, in accordance with embodiments of this disclosure. For example, slit valves 111 (e.g., protective liners, slit door liners, or the like), process chamber liners, plasma screens, cathode sleeves, showerheads, and other components may be coating with a resistant coating including a polymer sealant and resistant particles, in accordance with aspects of the present disclosure.

Other processes may be carried out as well. The load lock apparatus 107A, 107B may be adapted to interface with a factory interface 117 or other system component, that may receive substrates 110 from substrate carriers 119 (e.g., Front Opening Unified Pods (FOUPs)) that may be docked at load ports of the factory interface 117, for example. The factory interface robot 121 (shown dotted) may be used to transfer the substrates 110 between the substrate carriers 119 and each load lock apparatus 107A, 107B. Transfers of the substrates 110 may be carried out in any sequence or direction. The factory interface robot 121 may be identical (or similar) to the transfer chamber robot 101 in some embodiments, but may further include a mechanism to allow the factory interface robot to move in either lateral direction and indicated by arrow 123. Any other suitable robot may be used as the factory interface robot 121. In some embodiments, system 100 may be coupled to (e.g., interface with) a metrology system, e.g., an integrated metrology system, an inline metrology system, etc.

In embodiments, and by way of exemplified explanation for any robot, the transfer chamber robot 101 includes at least one arm 113 (e.g., a robot arm) and at least one end effector 115 coupled to the arm 113. The end effector 115 is controllable by the transfer chamber robot 101 in order to pick up a substrate 110 from a load lock apparatus 107A or 107B, guide the substrate 110 through one of the slit valves 111 of a chamber 103, and accurately place the substrate 110 onto a substrate support of the chamber 103. In some embodiments, end effector 115 may include a blade for supporting substrate 110. In some embodiments, end effector 115 may support a first portion of substrate 110, e.g., may be ring-shaped enabling some portion of substrate 110 to be visible from the bottom while substrate 110 is supported by end effector 115.

Any substrate transfer system (e.g., robot) may include one or more motors for moving at least a portion of the transfer system. For example, a motor may be utilized to extend one or more arms for transferring substrates in and out of various process chambers, metrology chambers, load lock chambers, or the like. A motor may be utilized to enable factory interface robot 121 to travel linearly between various substrate carriers 119.

In some embodiments, further robots may be present within one or more of the chambers 103. For example, a chamber including one or more metrology apparatuses may include a stage for moving a substrate within the metrology apparatuses. The stage may be utilized for adjusting a portion of a substrate that is within a field of view of a metrology apparatus. In some embodiments, one or more motors may be associated with the stage. One or more motor associated with the stage may be linear motors. For example, a metrology system may include a stage with one linear motor for generating linear motion of the substrate and one rotational motor for generating rotational motion of the substrate.

A controller 109 (e.g., a tool and equipment controller) may control various aspects of the processing system 100, e.g., gas pressure in the chamber 103, individual gas flows, spatial flow ratios, temperature of various chamber components, and radio frequency (RF) or electrical state of the chamber 103. Controller 109 may receive signals from and send commands to the factory interface robot 121, the transfer chamber robot 101, one or more sensors, and/or other processing components of processing system 100. Controller 109 may thus control the initiation and cessation of processing, may adjust a deposition rate, type or mix of deposition composition, and the like. The controller 109 may further receive and process sensing data from various sensors, e.g., sensors associated with processing system 100, sensors of various motors generating position error data, sensors reporting on conditions within one or more chambers of processing system 100, etc.

Controller 109 and/or processing device 130 may be and/or include a computing device such as a personal computer, a server computer, a programmable logic controller (PLC), a microcontroller, and so on. The controller 109 and/or the processing device 130 may include (or be) one or more processing devices, which may be general-purpose processing devices such as a microprocessor, central processing unit, or the like. More particularly, the processing device may be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device may also be one or more special-purpose processing devices such as an application specific integrated circuit (ASIC), a field programmable gate array (FPGA), a digital signal processor (DSP), network processor, or the like. Controller 109 and/or processing device 130 may include a data storage device (e.g., one or more disk drives and/or solid state drives), a main memory, a static memory, a network interface, and/or other components. Processing device 130 may execute instructions to perform any one or more of the methodologies and/or embodiments described herein. The instructions may be stored on a computer readable storage medium, which may include the main memory, static memory, secondary storage and/or processing device (during execution of the instructions).

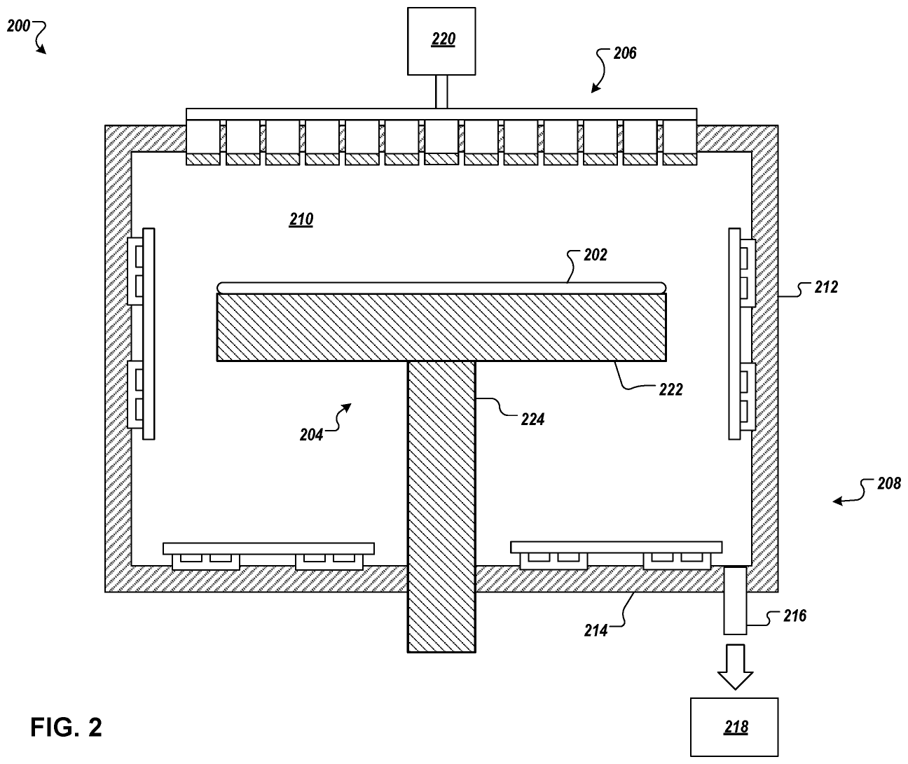

FIG. 2 is a sectional view of a processing chamber 200 having one or more chamber components that may be coated with a resistant coating including a polymer sealant and resistant particles, according to some embodiments. Processing chamber 200 may be used for processes in which components of processing chamber 200 are exposed to corrosive environments, such as plasma environments, dry etch environments, chemical or wet etch environments, etc. Processing chamber 200 may be used for processes in which a corrosive plasma environment having plasma processing conditions is provided. For example, the processing chamber 200 may be a chamber for a plasma etcher or plasma etch reactor, a plasma cleaner, and so forth. Examples of chamber components that may include such a resistant coating include a substrate support assembly 104, an electrostatic chuck (ESC), a ring (e.g., a process kit ring or single ring), a chamber wall, a chamber liner, a base, a gas distribution plate, a showerhead 206, a nozzle, a lid, a liner, a liner kit, a shield, a plasma screen, a flow equalizer, a cooling base, a chamber viewport, a chamber lid, and so on. The coating applied to one or more components of the chamber may include a polymer component and a ceramic component.

In one embodiment, processing chamber 200 includes a chamber body 208 and a showerhead 206 that enclose an interior volume 210. The showerhead may include a showerhead base and a showerhead gas distribution plate. Alternatively, the showerhead 206 may be replaced by a lid and a nozzle in some embodiments. The chamber body 208 may be fabricated from aluminum, stainless steel or other suitable material. The chamber body 208 generally includes sidewalls 212 and a bottom 214. Any of the showerhead 206 (or lid and/or nozzle), sidewalls 212 and/or bottom 214 may include a corrosion resistant coating, an accordance with the present disclosure.

An exhaust port 216 may be defined in the chamber body 208, and may couple the interior volume 210 to a pump system 218. The pump system 218 may include one or more pumps and throttle valves utilized to evacuate and regulate the pressure of the interior volume 210 of processing chamber 200.

Showerhead 206 may be supported on the sidewall 212 of the chamber body 208. The showerhead 206 (or lid) may be opened to allow access to the interior volume 210 of processing chamber 200, and may provide a seal for processing chamber 200 while closed. A gas panel 220 may be coupled to processing chamber 200 to provide process and/or cleaning gases to the interior volume 210 through showerhead 206 or lid and nozzle. Showerhead 206 is used for processing chambers used for dielectric etch (etching of dielectric materials). The showerhead 206 includes a gas distribution plate (GDP) having multiple gas delivery holes throughout the GDP. Showerhead 206 may include the GDP bonded to an aluminum base or an anodized aluminum base. The GDP may be made from Si or SiC, or may be a ceramic such as Y₂O₃, Al₂O₃, YAG, and so forth. Showerhead 206 may include a resistant coating, including a porous coating material, polymer sealant, and resistant particles, e.g., resistant nanoparticles.

For processing chambers used for conductor etch (etching of conductive materials), a lid may be used rather than a showerhead. The lid may include a center nozzle that fits into a center hole of the lid. The lid may be a ceramic such as Al₂O₃, Y₂O₃, YAG, or a ceramic compound comprising Y₄Al₂O₉ and a solid-solution of Y₂O₃—ZrO₂. The nozzle may also be a ceramic, such as Y₂O₃, YAG, or the ceramic compound comprising Y₄Al₂O₉ and a solid-solution of Y₂O₃—ZrO₂. The lid, showerhead base, GDP and/or nozzle may be coated with a arcing and plasma resistant coating layer according to an embodiment.

Examples of processing gases that may be used to process substrates in the processing chamber 100 include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases). The substrate support assembly 204 is disposed in the interior volume 210 of the processing chamber 200 below the showerhead 206 or lid. The substrate support assembly 204 holds the substrate 202 during processing. A ring (e.g., a single ring) may cover a portion of the support assembly 204 (e.g., susceptor 222), and may protect the covered portion from exposure to plasma during processing. The ring may be silicon or quartz in one embodiment. Substrate support assembly 204 may include a pedestal 224, and a susceptor 222.

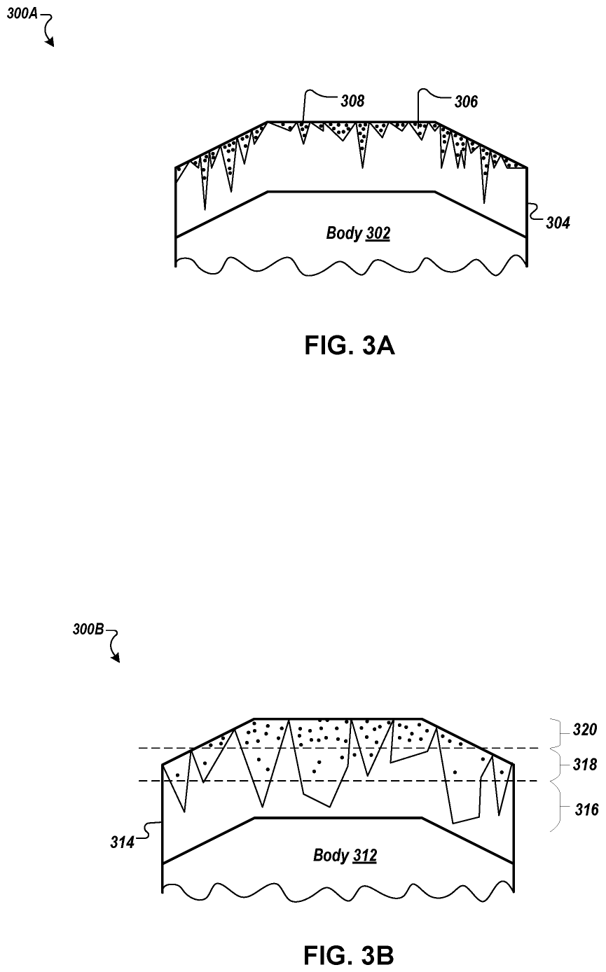

FIGS. 3A-B depict sectional views of exemplary coated articles, according to some embodiments. FIG. 3A illustrates a coated article 300A having a body 302 and coating 304. Body 302 may be a body of any of various chamber components including but not limited to a chamber liner, a slit door liner, a plasma screen, a cathode sleeve, substrate support assembly, an electrostatic chuck (ESC), a ring (e.g., a process kit ring or single ring), a chamber wall, a base, a gas distribution plate, a nozzle, a lid, a liner, a liner kit, a shield, a flow equalizer, a cooling base, a chamber viewport, a chamber lid, and so on. The body may be made from a metal (such as aluminum, stainless steel, etc.), a ceramic, a metal-ceramic composite, a polymer, a polymer ceramic composite, or other suitable materials.

Coating 304 may be applied by any application method that is appropriate for a selected material, the body 302, intended use of article 300A, or the like. For example, coating 304 may be provided by plasma electrolytic oxidation, thermal spraying, plasma spraying, physical vapor deposition, ion assisted deposition, or the like.

In some embodiments, a coating 304 applied directly to body 302 may include pores, gaps, channels, cracks, or the like. The porosity of coating 304 may provide access by the corrosive environment to portions of the coating deep beneath the surface of the coating. The porosity of coating 304 may provide access by a corrosive environment to body 302 beneath the coating 304. In some embodiments, a method of application of coating 304, a chosen material for coating 304, or the like may result in porosity of coating 304. In some embodiments, geometry and/or orientation of body 302 may result in porosity of coating 304. For example, in physical vapor deposition processes (PVD), surfaces that are at angles far from perpendicular to a direction of incidence of the vapor deposition may exhibit increased porosity, a columnar structure, increased gaps or crack in the coating, or the like.

Coating 304 may be of any material that generates a protective or resistant coating on body 302. Coating 304 may be of a ceramic material. Coating 304 may be of a metal oxide material. Coating 304 may be of a material including fluorine. Coating 304 may include ceramic materials (e.g., plasma resistant ceramic materials), such as ceramic oxides (e.g., alumina Al₂O₃, yttria Y₂O₃, yttrium aluminum garnet Y₃Al₅O₁₂, yttrium aluminum perovskite YAlO₃, zirconia ZrO₂, silicon dioxide SiO₂, Er₂O₃, ErAlₓO_{y}, YAlₓO_{y}, YZrₓO_{y} and YZrₓAl_{y}O_{z}, Gd₂O₃, Yb₂O₃, Y₂O₃ stabilized ZrO₂ (YSZ), Er₃Al₅O₁₂ (EAG), a Y₂O₃—ZrO₂ solid solution, or a composite ceramic comprising Y₄Al₂O₉ and a solid solution of Y₂O₃—ZrO₂, etc.), ceramic carbides (e.g., silicon carbide SiC, silicon-silicon carbide Si—SiC, boron carbide B₄C, etc.), nitride based ceramics (e.g., aluminum nitride AlN, silicon nitride SiN, etc.), yttrium fluoride YF₃, yttrium oxyfluoride YOF, magnesium oxide, other ceramic materials, or combinations of materials. Some additional examples of ceramic oxides that may be used for the plasma resistant coating layer 208 include yttrium-based oxides, erbium-based oxides, and so on. Additionally, ceramic fluorides and/or oxyfluorides may be used for the plasma resistant coating layer 208. Examples include YOₓF_{y}. YF₃, and so on. Coating 304 may be of any appropriate thickness, from a few thousandths of an inch to a few hundredths of an inch thick.

In one embodiment, the plasma resistant coating 304 is or includes a metal oxide coating that includes or consists of a solid solution of yttria and zirconia (Y₂O₃—ZrO₂). The solid solution of Y₂O₃—ZrO₂ may include 20-80 mol % Y₂O₃ and 20-80 mol % ZrO₂ in one embodiment. In a further embodiment, the solid solution of Y₂O₃—ZrO₂ includes 30-70 mol % Y₂O₃ and 30-70 mol % ZrO₂. In a further embodiment, the solid solution of Y₂O₃—ZrO₂ includes 40-60 mol % Y₂O₃ and 40-60 mol % ZrO₂. In a further embodiment, the solid solution of Y₂O₃—ZrO₂ includes 50-80 mol % Y₂O₃ and 20-50 mol % ZrO₂. In a further embodiment, the solid solution of Y₂O₃—ZrO₂ includes 60-70 mol % Y₂O₃ and 30-40 mol % ZrO₂. In other examples, the solid solution of Y₂O₃—ZrO₂ may include 45-85 mol % Y₂O₃ and 15-60 mol % ZrO₂, 55-75 mol % Y₂O₃ and 25-45 mol % ZrO₂, 58-62 mol % Y₂O₃ and 38-42 mol % ZrO₂, and 68-72 mol % Y₂O₃ and 28-32 mol % ZrO₂.

In various embodiments, the plasma resistant coating 304 may be composed of Y₃Al₅O₁₂ (YAG), Y₄Al₂O₉ (YAM), Er₃Al₅O₁₂ (EAG), Gd₃Al₅O₁₂ (GAG), YAlO₃ (YAP), Er₄Al₂O₉ (EAM), ErAlO₃ (EAP), Gd₄Al₂O₉ (GdAM), GdAlO₃ (GdAP), Nd₃Al₅O₁₂ (NdAG), Nd₄Al₂O₉ (NdAM), NdAlO₃ (NdAP), and/or a ceramic compound comprising Y₄Al₂O₉ and a solid-solution of Y₂O₃—ZrO₂. The resistant coating 304 may also be Er—Y compositions (e.g., Er 80 wt % and Y 20 wt %), Er—Al—Y compositions (e.g., Er 70 wt %, Al 10 wt %, and Y 20 wt %), Er—Y—Zr compositions (e.g., Er 70 wt %, Y 20 wt % and Zr 10 wt %), or Er—Al compositions (e.g., Er 80 wt % and Al 20 wt %). Note that wt % means percentage by weight. In contrast, mol % is molar ratio.

Resistant coating 304 may also be based on a solid solution formed by any of the aforementioned ceramics. With reference to the ceramic compound comprising Y₄Al₂O₉ and a solid-solution of Y₂O₃—ZrO₂, in one embodiment, the ceramic compound includes 62.93 molar ratio (mol %) Y₂O₃, 23.23 mol % ZrO₂ and 13.94 mol % Al₂O₃. In another embodiment, the ceramic compound can include Y₂O₃ in a range of 50-75 mol %, ZrO₂ in a range of 10-30 mol % and Al₂O₃ in a range of 10-30 mol %. In another embodiment, the ceramic compound can include Y₂O₃ in a range of 40-100 mol %, ZrO₂ in a range of 0-60 mol % and Al₂O₃ in a range of 0-10 mol %. In another embodiment, the ceramic compound can include Y₂O₃ in a range of 40-60 mol %, ZrO₂ in a range of 30-50 mol % and Al₂O₃ in a range of 10-20 mol %. In another embodiment, the ceramic compound can include Y₂O₃ in a range of 40-50 mol %, ZrO₂ in a range of 20-40 mol % and Al₂O₃ in a range of 20-40 mol %. In another embodiment, the ceramic compound can include Y₂O₃ in a range of 70-90 mol %, ZrO₂ in a range of 0-20 mol % and Al₂O₃ in a range of 10-20 mol %. In another embodiment, the ceramic compound can include Y₂O₃ in a range of 60-80 mol %, ZrO₂ in a range of 0-10 mol % and Al₂O₃ in a range of 20-40 mol %. In another embodiment, the ceramic compound can include Y₂O₃ in a range of 40-60 mol %, ZrO₂ in a range of 0-20 mol % and Al₂O₃ in a range of 30-40 mol %. In other embodiments, other distributions may also be used for the ceramic compound.

Any of the aforementioned plasma resistant coating layers 208 may contain one or more dopants that combined comprise up to about 2 mol % of the coating. Such dopants may be rare earth oxides from the lanthanide series, such as Er (erbium), Ce (cerium), Gd (gadolinium), Yb (ytterbium), Lu (lutetium), and so on. Such dopants may additionally or alternatively include Al (aluminum) and/or Si (silicon).

Article 300A further includes sealant layer 306. Sealant layer 306 may include a sealant disposed within pores of coating 304. Sealant layer 306 may include a polymer sealant disposed within pores, gaps, channels, or the like of coating 304. Disposing the polymer sealant of sealant layer 306 may include providing a polymer sealant precursor to coating 304. The polymer sealant precursor may be a self-curing precursor, e.g., a liquid polymer precursor that cures to a solid polymer at ambient conditions, such as the Dichtol family of sealants produced by Diamant. The polymer sealant precursor may be a precursor that cures under different conditions, such as a mixed precursor that begins a curing process upon mixing two or more precursor components. The polymer sealant precursor may cure in a target atmosphere, such as upon exposure to certain pressure ranges, gases, temperature ranges, or the like. Coating layer 204 may be applied using any technique suitable for depositing a thin layer of polymer on a body, such as aerosol coating, dip coating, blade coating, spin coating, brushing, etc. In some embodiments, sealant layer 306 may infiltrate essentially all accessible pores of coating 304. In some embodiments, sealant layer 306 may infiltrate pores to a depth. Sealant may infiltrate pores to a depth of around 100 μm, from 50 to 200 μm, from 10 to 500 μm, or to another depth. In some embodiments, application of the sealant precursor may be performed under target atmospheric conditions, e.g., in a vacuum (for example, to remove gas from the pores before applying the polymer sealant precursor), under pressure (for example, to provide pressure to force sealant precursor into the pores), at an elevated temperature (for example, to enable or speed up polymer curing), or other conditions.

In some embodiments, sealant layer 306 may be selected to be of a material that will interact with a process gas intended for use with article 300A that will improve one or more properties of sealant layer 306. For example, sealant layer 306 may be selected to interact with a process gas to expand sealant layer 306, which may enable sealant layer 306 to be at least partially self-healing. Sealant layer 306 may be selected to interact with fluorine gas to volumetrically expand. Particles 308 of sealant layer 306 may be configured to react with process gas (e.g., fluorine gas). Particles 308 may be selected to be of a material that increases in volume upon reacting with one or more process gases (e.g., fluorine gas).

Sealant layer 306 includes particles 308. Particles 308 are of a resistant material, disposed within sealant layer 306. Particles 308 may improve resistance of coating 304 to a corrosive environment, e.g., compared to a coating with a sealant layer without resistant particles. Particles 308 may be of a metal oxide material. Particles 308 may be of a ceramic material. Particles 308 may be nanoparticles, e.g., ceramic nanoparticles. Particles 308 may be of yttrium oxyfluoride, yttrium fluoride, yttrium oxide, aluminum oxide, magnesium oxide, silicon carbide, zirconium oxide, etc. Particles 308 may be of the same materials described in connection with coating 304. In some embodiments, the material of particles 308 may be the same as the material of coating 304 in which the particles are disposed. In some embodiments, the material of particles 308 may be different than the material of coating 304.

Particles 308 may be selected to be of a material that will interact with a gas intended to be proximate article 300A to adjust properties of particles 308. For example, particles 308 may be of a material that interacts with a process gas, and causes properties of particles 308 to change. Size, hardness, density, or the like may be target property adjustments of particles 308 upon introduction to process gas. For example, particles 308 may be of a material that expands upon exposure to process gas (e.g., fluorine), which may improve resistance of a coating to corrosive (e.g., fluorine-containing) environments.

In some embodiments, particles 308 may be disposed within a polymer sealant precursor before the polymer sealant precursor is applied to body 302. Particles 308 may be of any target concentration within the polymer sealant and/or polymer sealant precursor. For example, particles 308 may be present at a concentration of about 20 weight percent in the polymer sealant. Particles 308 may be present between 10 and 30 weight percent, between 5 and 35 weight percent, between 3 and 40 weight percent, or other concentrations within the polymer sealant. In some embodiments, the polymer sealant precursor may include a dispersant, e.g., for dispersing resistant nanoparticles. The polymer sealant may include polyvinyl alcohol, sulphonates, surfactants, or other dispersing agents. In some embodiments, suspending particles into the polymer sealant precursor may include agitation, sonication, or other techniques for suspending particles. Particles 308 may be nanoparticles. Particles 308 may be between 10 nm and 500 nm in diameter. Particles 308 may be between 50 nm and 200 nm in diameter. Particles 308 may be approximately 100 nm in diameter. Utilizing nanoparticles as particles 308 may improve penetration of particles into voids (e.g., pores) of a coating compared to other particle sizes. Utilizing nanoparticles as particles 308 may reduce a risk of contamination of a substrate during processing if the particles 308 are released during substrate processing. Nanoparticles may be more likely than other sizes of particles to be evacuated by a gas exhaust system before reaching a substrate, and be less likely to generate a defect that impacts function of the substrate than other sizes of particles.

FIG. 3B depicts a coated article 300B including body 312 and a number of coating layers. Body 312 may be any of various chamber components, such as those discussed above in connection with body 302 of FIG. 3A. Body 312 may be composed of a variety of materials, such as those discussed above in connection with body 302. Coating 314 may provide a corrosion resistance to body 312. Coating 314 may include a polymer material. Coating 314 may share many features in common with coating 304 of FIG. 3A. Coating 314 may include one or more ceramic materials, including ceramic oxides, ceramic carbides, ceramic nitrides, etc.

Coating 314 includes multiple layers, layers 316, 318, and 320. Layers of coating 314 are distinguished by concentration of particles 322. A first coating layer 316 may have a low concentration of particles disposed within the polymer sealant. In some embodiments, the first coating layer 316 may have no particles, or be applied to body 312 with no particles disposed therein. A second coating layer 318 may have a larger concentration of particles, and third layer 320 a still higher concentration of particles. Any number of layers of various particle densities may be included in coating 314, e.g., a single layer as depicted in article 300A, two layers, three layers, or more layers. In some embodiments, multiple applications of polymer precursor may be applied to body 312 with different concentrations of particles suspended in the precursor to generate layers of coating 314. In some embodiments, applications of polymer precursor may be cured before applying a later application. For example, polymer precursor of first layer 316 may be applied (with a first concentration of particles). The polymer precursor may be cured to a polymer sealant. Polymer precursor of second layer 318 may then be applied (with a second, higher concentration of particles) and cured, polymer precursor of third layer 320 may be applied (with a third concentration of particles) and cured, etc. In some embodiments, multiple applications of polymer precursor may be applied before curing operations of one or more previous layers. In some embodiments, polymer precursor may be applied to body 312, and particles may be applied to the polymer precursor to impregnate the particles into the polymer. For example, polymer precursor may be applied to body 312, and subsequently particles 322 may be applied to the polymer precursor. Particles 322 may be allowed to migrate or disperse into the polymer precursor, e.g., generating a concentration gradient of particles 322 in the polymer sealant. Particles 322 may be pressed into the polymer precursor, e.g., by rolling or pressing the particles into the pores of coating 314.

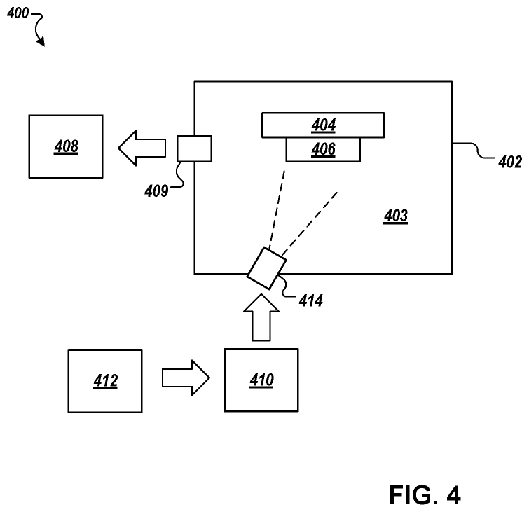

FIGS. 4-7 depict a few methods and/or apparatuses for applying coatings to a component, according to some embodiments. FIG. 4 illustrates an exemplary architecture of a deposition system 400 for performing aerosol or thermal spray deposition, according to some embodiments. System 400 may be used for applying various coatings to a component of processing equipment. System 400 may be used to apply coatings of many types of materials, including polymer coatings (e.g., high dielectric strength coatings), ceramic coatings (e.g., plasma resistant coatings), coatings including multiple components (such as a polymer phase and a ceramic phase), or other types of coatings. System 400 may provide a coating that is porous, includes gaps or cracks, or the like. In some embodiments, system 400 may be utilized in a thermal spray system that deposits a hot coating, which may crack, flake, fracture, or otherwise introduce imperfections as the coating cools.

System 400 includes a deposition chamber 402. The deposition chamber may include a stage 404 for mounting a component 406 to be coated (e.g., body 302 of FIG. 3A, body 312 of FIG. 3B, etc.). Ambient pressure in interior volume 403 of chamber 402 may be reduced via a vacuum system 408, coupled to inner volume 403 via exhaust port 409 defined in the body of chamber 402. In some embodiments, deposition may occur at atmospheric pressures, ambient pressures, may not occur in a vacuum, or the like. Chamber 410 contains a coating powder for coating component 406 for use in aerosol deposition, such as a metal oxide powder, a ceramic powder, a yttrium oxyfluoride powder, a mixture of powders, etc. Chamber 410 may include material for use in a thermal spray deposition, e.g., material to be melted or brought to an elevated temperature for deposition on component 406. Chamber 410 is coupled to gas container 412. The coating material in chamber 410 may be in the form of a fine powder, e.g., may have particles ranging from a few μm to a few hundred μm in size. A carrier gas flows from gas container 412, through aerosol chamber 410 to interior volume 403. The carrier gas propels the coating powder through nozzle 414 for directing the coating powder onto component 406 to form a coating. In some embodiments, coating material may be increased in temperature for thermal spray deposition before being introduced to nozzle 414. In some embodiments, coating material may be provided to nozzle 414 and increased in temperature in nozzle 414 for thermal spray deposition of component 406.

The component 406 may be a component used for semiconductor manufacturing. Component 406 may be a component of an etch reactor, a thermal reactor, a semiconductor processing chamber, or the like. Examples of possible components include a lid, a substrate support, process kit rings, a chamber liner, a nozzle, a showerhead, a wall, a base, a gas distribution plate, etc. Component 406 may be formed of a material such as aluminum, silicon, quartz, a metal oxide, a ceramic compound, a polymer, a composite, etc.

In some embodiments, the surface of component 406 may be polished to reduce a surface roughness of component 406. Reducing surface roughness may improve coating uniformity. In some embodiments, surface roughness is reduced until it is lower than the target thickness of a coating layer. In some embodiments, not all areas of component 406 are to be coated. Areas of component 406 may be masked or shielded, or otherwise removed from the area accessed by the aerosol powder. In some embodiments, coating may be removed from areas that are not to be coated after coating.

Component 406 may be mounted on stage 404 in deposition chamber 402 during deposition of a coating. Stage 404 may be a moveable stage (e.g., motorized stage) that can be moved in one, two, or three dimensions, and/or rotated in one or more dimensions, such that stage 404 can be moved to different positions to facilitate coating of component 406 with coating propelled from nozzle 414. For example, stage 404 may be moved to coat different portions or sides of component 406. Nozzle 414 may be selectively aimed at certain portions of component 406 from various angles and orientations.

In some embodiments, deposition chamber 402 may be evacuated using vacuum system 408. Providing a vacuum environment in inner volume 403 may facilitate application of the coating. For example, the coating powder propelled from nozzle 414 encounters less resistance as it travels to component 406 when inner volume 403 is under vacuum. Coating powder May impact component 406 more regularly, at a higher rate of speed, etc., which may facilitate adherence to component 406, facilitate formation of a coating, reduce wasted coating material, etc.

Gas container 412 holds a pressurized carrier gas. Pressurized carrier gasses that may be used include inert gasses, such as argon, nitrogen, krypton, etc. The pressurized carrier gas travels under pressure from gas container 412 to chamber 410. As the pressurized gas travels from chamber 410 to nozzle 414, the carrier gas propels some of the coating material from chamber 410 toward nozzle 414.

In some embodiments, system 400 may be used to deposit a single material onto one or more surfaces of component 406. In some embodiments, system 400 may be used to deposit multiple materials onto component 406. In some embodiments, a polymer layer including multiple polymers may be deposited on component 406. In some embodiments, a ceramic layer including multiple ceramic materials may be deposited on component 406. In some embodiments, a material including a polymer phase and a ceramic phase may be deposited on component 406. Multiple materials may be co-deposited by providing a mixture of powdered materials to chamber 410. In an alternate embodiment, two or more aerosol chambers may be coupled to pressurized gas and to nozzle 414, with each providing material to nozzle 414 separately. In an alternate embodiment, multiple nozzles may receive material from multiple aerosol chambers coupled to pressurized carrier gas. These embodiments may allow multiple materials to be deposited simultaneously.

In some embodiments, a coating deposited by system 400 may be porous. A porous coating may be sealed by disposing a polymer sealant within pores of the coating. The porous coating may be sealed by applying a polymer sealant precursor to the coating and allowing the polymer sealant precursor to cure into a polymer sealant. The polymer sealant may include resistant particles.

As the carrier gas propelling a suspension of coating material (e.g., powder, melted droplets of coating material, etc.) enters deposition chamber 402 from nozzle 414, the coating material is propelled towards component 406. In one embodiment, the carrier gas is pressurized such that the coating powder is propelled towards component 406 at a rate between 150 m/s and 500 m/s. In some embodiments, particle size of the coating powder(s), and pressure(s) of carrier gas(ses) may be tuned for a target velocity distribution of coating powder.

In some embodiments, nozzle 414 is formed to be wear resistant. Due to movement of coating powder through nozzle 414 at high velocity, nozzle 414 can rapidly wear and degrade. Nozzle 414 may be formed in a shape and from a material such that wear is reduced.

In some embodiments, upon impacting component 406 particles of a coating powder fracture and deform from kinetic energy to produce a layer that adheres to component 406. As the application of coating powder continues, the particles become a coating or film by bonding to themselves. The coating on component 406 continues to grow by continuous collision of the particle of the coating powder on component 406. In some embodiments, particles mechanically collide with each other and with the substrate at a high speed under a vacuum to break into smaller pieces to form a dense layer, rather than melting. In some embodiments, crystal structure of particles of coating powder in chamber 410 is preserved through application to component 406. In some embodiments, melting of particles may occur when kinetic energy is converted to thermal energy. In some embodiments, aerosol deposition may be performed at room temperature, or between 15° C. and 35° C. In some embodiments, component 406 does not need to be heated and the aerosol application process may not significantly increase the temperature of component 406. Applications such as this may be used to coat assemblies that may be damaged in an environment of elevated temperature. For example, components formed of multiple parts affixed together with a bonding layer that melts at a low temperature may be damaged in a deposition process carried out at elevated temperatures. As a further example, components formed of multiple parts of different materials with different thermal expansion properties may be damaged as the parts expand at different rates, to different sizes, etc., during deposition. Such components may be less likely to be damaged by coating at ambient temperatures.

In some embodiments, aerosol deposition may be performed at an elevated temperature. In some embodiments, component 406 may be heated before or during aerosol deposition. Such heating may encourage melting of coating powder. In some embodiments, after deposition occurs, component 406 may be placed in an oven for heating of the component and coating material for a time. The temperature of component 406 and the coating may increase, such that the coating partially or fully melts. The coating may be allowed to flow over the surface of component 406, for example to improve uniformity of the coating, to allow the coating to reach new areas of the surface of component 406, etc.

In some embodiments, the coated component may be subjected to a post-coating process. For example, a ceramic coating may be polished or ground after application to component 406. Coated components may be subjected to other post-coating processes, such as thermal treatment. A thermal treatment in some embodiments forms a coating interface between the coating and the component. For example, a yttria (Y₂O₃) coating over an alumina (Al₂O₃) component can form a yttrium aluminum garnet (YAG) layer that aids in adhesion and provides further protection to the component. A barrier layer may reduce the occurrence of delamination, chipping, flaking, peeling, etc. Thermal treatment may also alter the chemical composition of the coating—a dual yttria/alumina coating may be converted to a YAG coating by thermal treatment.

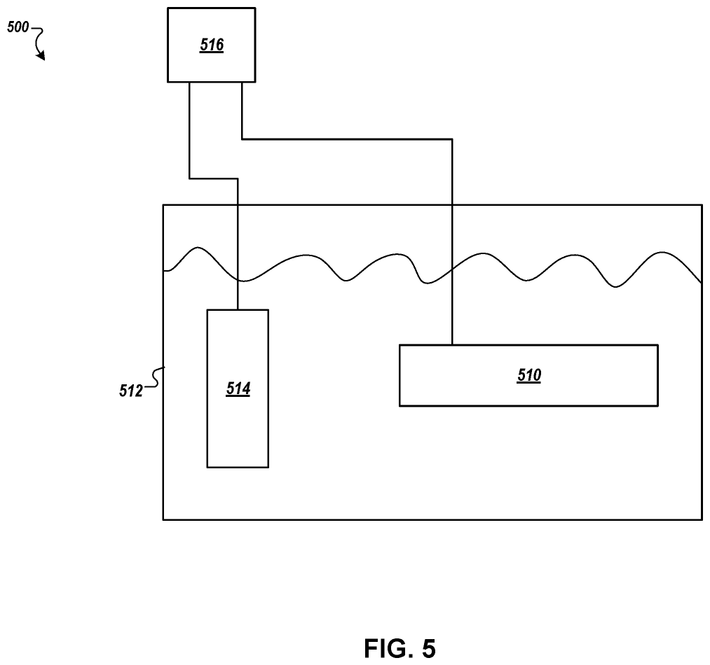

FIG. 5 depicts an apparatus 500 for performing plasma electrolytic oxidation (PEO) to generate a coating layer on a body 510, according to some embodiments. In PEO, body 510 (e.g., a component of a manufacturing system) is at least partially submerged in an electrolyte bath 512. The electrolyte bath may be an aqueous solution of salts, additives, or the like for forming a target coating on body 510. The electrolyte bath may be an alkaline solution. The electrolyte bath 512 may include potassium hydroxide KOH.

An electrode 514 is also in contact with electrolyte bath 512. In some embodiments, the electrode 514 may be at least partially submerged in the electrolyte bath 512. In some embodiments, the electrode 514 may be integrated into the electrolyte bath 512, e.g., at least a portion of a wall of electrolyte bath 512 may act as electrode 514.

Electrode 514 and body 510 are coupled to a voltage supply 516, which applies a potential difference between electrode 514 and body 510. In some embodiments, the voltage is a DC voltage. In some embodiments, the voltage is an AC voltage. In some embodiments, an alternating current is applied. In some embodiments, the body 510 may act as an anode (e.g., the positively charged electrode) and electrode 514 may act as the cathode (negative electrode). A high voltage may be applied between the body 510 and electrode 514, e.g., potentially over 200 V.

In some embodiments, electrical potential between body 510 and electrode 514 may reach a critical value at which discharge occurs from a metal surface into the electrolyte. The discharge (e.g., arcs) may lead to the formation of plasma in the vicinity of the metal surface (e.g., surface of body 510). In the presence of the plasma induced by the high voltages applied to the components of apparatus 500, oxygen ions may be driven to the metal surface (e.g., of body 510). The oxygen ions may react with the surface of body 510, generating a hard oxide-layer which may be thick and porous, in some embodiments. The porous coating layer may later be augmented with a polymer sealant, including resistant particles, in accordance with aspects of this disclosure.

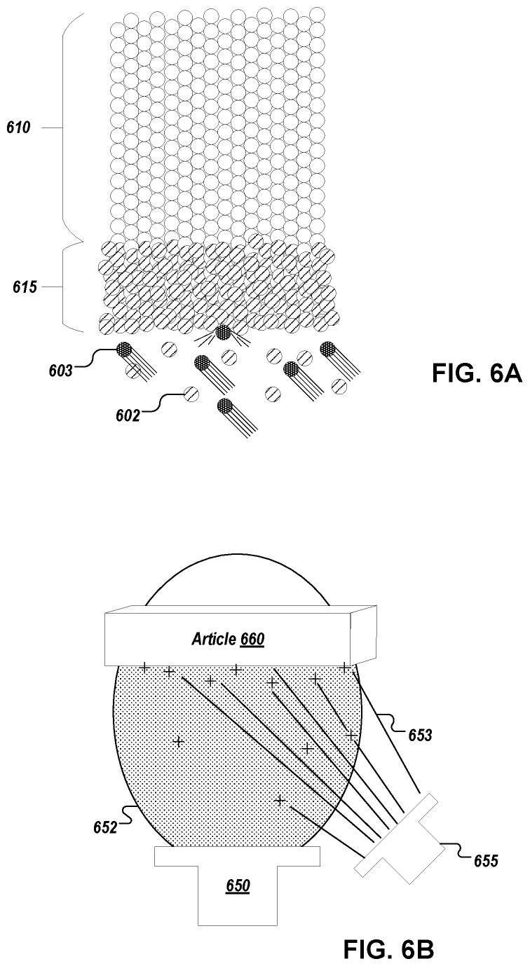

FIGS. 6A-B depict a mechanism and apparatus for performing deposition techniques utilizing energetic particles, according to some embodiments. FIG. 6A depicts a deposition mechanism applicable to a variety of deposition techniques utilizing energetic particles such as ion assisted deposition (IAD). Exemplary IAD methods include deposition processes which incorporate ion bombardment, such as evaporation (e.g., activated reactive evaporation (ARE)) and sputtering in the presence of ion bombardment to form coatings as described herein. Any of the IAD methods may be performed in the presence of a reactive gas species, such as O₂, N₂, halogens, etc.

As shown, a thin coating layer 615 is formed by an accumulation of deposition materials 602 in the presence of energetic particles 603 such as ions. The deposition materials 602 include atoms, ions, radicals, or their mixture. The energetic particles 603 may impinge and compact the thin final plasma resistant coating layer 615 as it is formed.

In some embodiments, a coating layer may be applied by physical vapor deposition (PVD), chemical vapor deposition (CVD), sputtering, or other deposition methods. In some embodiments, IAD methods may augment such deposition techniques. In some embodiments, a resistant coating applied by another method may be utilized for generating a resistant coating including resistant particles in a polymer sealant of the coating, without performing IAD methods for augmenting the deposition.

In one embodiment, IAD is utilized to augment a thin coating layer 615, as previously described elsewhere herein (e.g., utilizing aerosol deposition, thermal spray deposition, PVD, sputtering, plasma electrolytic oxidation, or the like). FIG. 6B depicts a schematic of an IAD deposition apparatus. As shown, a material source 650 provides a flux of deposition materials 652 for deposition on article 6460 while an energetic particle source 655 provides a flux of the energetic particles 653, both of which impinge upon the article 660 throughout the IAD process. The energetic particle source 655 may be an oxygen or other ion source. The energetic particle source 655 may also provide other types of energetic particles such as inert radicals, neutron atoms, and nano-sized particles which come from particle generation sources (e.g., from plasma, reactive gases or from the material source that provide the deposition materials). IAD may utilize one or more plasmas or beams to provide the material and energetic ion sources. Reactive species may also be provided during deposition of the plasma resistant coating.

With IAD processes, the energetic particles 653 may be controlled by the energetic ion (or other particle) source 655 independently of other deposition parameters. According to the energy (e.g., velocity), density and incident angle of the energetic ion flux, composition, structure, crystalline orientation and grain size of the thin film protective layer may be manipulated. Additional parameters that may be adjusted are a temperature of the article during deposition as well as the duration of the deposition. The ion energy may be roughly categorized into low energy ion assist and high energy ion assist. The ions are projected with a higher velocity with high energy ion assist than with low energy ion assist. In general superior performance has been shown with high energy ion assist. Substrate (article) temperature during deposition may be roughly divided into low temperature (around 120-150° C. in one embodiment which is typical room temperature) and high temperature (around 270° C. in one embodiment).

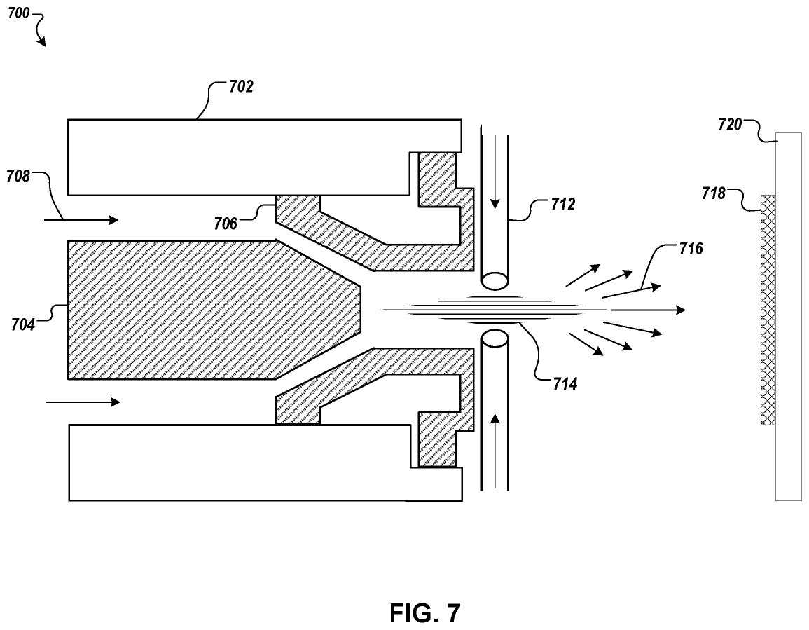

FIG. 7 depicts a schematic drawing of a plasma spray deposition apparatus 700 used for spray deposition techniques, according to some embodiments. The plasma spray apparatus 700 may include a casing 702 that encases a nozzle anode 706 and a cathode 704. The casing 702 permits gas flow 708 through the plasma spray device 700 and between the nozzle anode 706 and the cathode 704. An external power source may be used to apply a voltage potential between the nozzle anode 706 and the cathode 704. The voltage potential produces an arc between the nozzle anode 706 and the cathode 704 that ignites the gas flow 708 to produce a plasma gas. The ignited plasma gas flow 708 produces a high-velocity plasma plume 714 that is directed out of the nozzle anode 706 and toward an article 720.

The plasma spray apparatus 700 may be located in a chamber or atmospheric booth. In some embodiments, the gas flow 708 may be a gas or gas mixture including, but not limited to argon, nitrogen, hydrogen, helium, and combinations thereof. In some embodiments, wherein the spray system is used to perform slurry plasma spray, the plasma spray apparatus 700 may be equipped with one or more fluid lines 712 to deliver a slurry into the plasma plume 714. In some embodiments, a particle stream 716 is generated from plasma plume 714 and is propelled towards article 720. Upon impact with the article 720, the particle stream forms a coating 718.

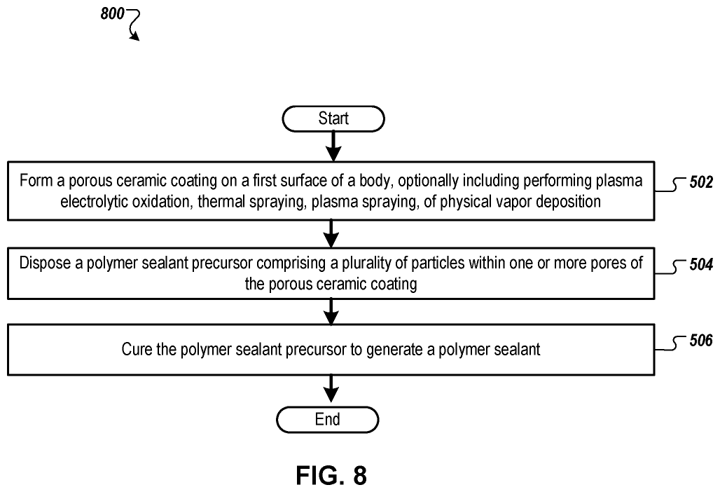

FIG. 8 is a flow diagram of a method 800 for generating a coating including a polymer sealant and resistant particles, according to some embodiments. At block 502, a porous ceramic coating is formed on a first surface of a body. In some embodiments, a porous ceramic coating may be formed that is a metal oxide, an inorganic material, or another protective and/or plasma corrosion resistant material. The body may be a metal body, ceramic body, metal/ceramic composite body, or another material. The body may be a component of a manufacturing system. The body may be a component of a process chamber. The body may be a process chamber liner, a slit door liner, a plasma screen, a cathode sleeve, a showerhead, or another chamber component.

In some embodiments, forming the porous coating may include depositing a coating material via one or more deposition techniques. The coating may be deposited via plasma electrolytic oxidation, thermal spraying, aerosol deposition, plasma spraying, physical vapor deposition (e.g., sputtering), chemical vapor deposition, or the like. The porous coating may be of yttrium oxyfluoride, yttrium fluoride, aluminum oxide, yttrium oxide, zirconium oxide, silicon carbide, magnesium oxide, or the like.

At block 504, a polymer sealant precursor is disposed within one or more pores of the porous ceramic coating. The polymer sealant precursor includes resistant particles, such as ceramic particles, metal oxide particles, particles of yttrium oxyfluoride, yttrium fluoride, aluminum oxide, yttrium oxide, zirconium oxide, silicon carbide, magnesium oxide, mixtures of materials, or the like. The resistant particles may be nanoparticles. The resistant particles may be between 10 nm and 500 nm in diameter. Disposing the polymer sealant precursor withing pores of the porous coating may include dipping the first surface of the body in the polymer sealant precursor. Disposing the polymer sealant precursor within pores of the coating may include spraying or brushing the polymer sealant precursor on the porous ceramic coating. The polymer sealant may infiltrate the pores up to a depth, e.g., 100 μm, between 10 μm and 1 mm, or the like. Disposing resistant particles in the polymer sealant may be performed before the sealant precursor is applied to the coating. Disposing resistant particles in the polymer sealant precursor may be performed after the sealant precursor is applied to the coating, e.g., applied to a surface of the coating after the sealant precursor is within the pores of the coating. The particles may subsequently be impregnated into the polymer sealant precursor, e.g., by rolling or pressing the surface of the coating to drive particles into the sealant precursor. In some embodiments, multiple applications of polymer sealant precursor may be performed. In some embodiments, multiple applications may be of different formulations, e.g., different precursors, precursors of different polymers, different particle materials, different particle concentrations, or the like. In some embodiments, a first application may have a lower concentration of particles than a later application.

At block 506, the polymer sealant precursor is cured to generate the polymer sealant. The polymer sealant precursor may be self-curing, e.g., may cure at ambient conditions. The polymer sealant precursor may be a mix curing precursor. The polymer sealant precursor may be a heat curing precursor. The polymer sealant precursor may be vacuum cured.

The preceding description sets forth numerous specific details such as examples of specific systems, components, methods, and so forth in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular implementations may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within +10%.

Although the operations of the methods herein are shown and described in a particular order, the order of operations of each method may be altered so that certain operations may be performed in an inverse order so that certain operations may be performed, at least in part, concurrently with other operations. In another embodiment, instructions or sub-operations of distinct operations may be in an intermittent and/or alternating manner.

It is understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A component comprising:
a body; and
a coating deposited on a surface of the metal body, the coating comprising:
a porous ceramic,
a polymer sealant, and
a plurality of particles disposed within the polymer sealant.

2. The component of claim 1, wherein the plurality of particles comprise metal oxide nanoparticles.

3. The component of claim 1, wherein the porous ceramic comprises one or more of:
aluminum oxide;
yttrium oxide;
yttrium oxyfluoride;
zirconium oxide;
magnesium oxide; or
silicon carbide.

4. The component of claim 1, wherein the plurality of particles comprise one or more of:
yttrium oxyfluoride;
yttrium fluoride;
aluminum oxide;
magnesium oxide; or
yttrium oxide.

5. The component of claim 1, wherein the component comprises:
a process chamber liner;
a slit door liner;
a plasma screen;
a cathode sleeve; or
a showerhead.

6. The component of claim 1, wherein the polymer sealant impregnates a surface of the porous ceramic to a depth of between 10 μm and 500 μm.

7. The component of claim 1, wherein the polymer sealant comprises a first portion and a second portion, wherein a distance between the surface of the metal body and the first portion of the polymer sealant is smaller than the distance between the surface of the metal body and the second portion of the polymer sealant, and wherein a concentration of particles disposed within the polymer sealant is greater in the second portion of the polymer sealant than the first portion of the polymer sealant.

8. A method, comprising:
forming a porous ceramic coating on a first surface of a body;
disposing a polymer sealant precursor comprising a plurality of particles within one or more pores of the porous ceramic coating; and
curing the polymer sealant precursor to generate a polymer sealant.

9. The method of claim 8, wherein the body comprises a component of a substrate chamber, comprising:
a process chamber liner;
a slit door liner;
a plasma screen;
a cathode sleeve; or
a showerhead.

10. The method of claim 8, wherein forming the porous ceramic coating on the first surface comprises performing one or more of:
plasma electrolytic oxidation;
thermal spraying;
plasma spraying; or
physical vapor deposition.

11. The method of claim 8, wherein the plurality of particles comprise one or more of:
yttrium oxyfluoride;
yttrium fluoride;
aluminum oxide;
magnesium oxide; or
yttrium oxide.

12. The method of claim 8, wherein forming the polymer sealant precursor comprises one or more of:
dipping the porous ceramic coating in the polymer sealant precursor;
spraying the polymer sealant precursor on the porous ceramic coating; or
brushing the polymer sealant precursor onto the porous ceramic coating.

13. The method of claim 8, wherein forming the polymer sealant precursor comprising the plurality of particles comprises:
applying the polymer sealant precursor to the porous ceramic coating;
applying the plurality of particles to the polymer sealant precursor that has been applied to the porous ceramic coating; and
impregnating the plurality of particles into the polymer sealant precursor.

14. The method of claim 8, wherein forming the polymer sealant comprising the plurality of particles comprises:
applying a first portion of the polymer sealant precursor to the porous ceramic coating, wherein the first portion of the polymer sealant precursor comprises a first concentration of particles; and
applying a second portion of the polymer sealant precursor after providing the first portion of the polymer sealant precursor, wherein the second portion of the polymer sealant precursor comprises a second concentration of particles, higher than the first concentration of particles.

15. A substrate processing chamber, comprising a component, wherein the component comprises:
a metal body; and
a coating deposited on a surface of the metal body, the coating comprising:
a porous ceramic,
a polymer sealant, and
a plurality of particles disposed within the polymer sealant.

16. The substrate processing chamber of claim 15, wherein the porous ceramic comprises one or more of:
aluminum oxide;
yttrium oxide;
yttrium oxyfluoride;
zirconium oxide;
magnesium oxide; or
silicon carbide.

17. The substrate processing chamber of claim 15, wherein the plurality of particles comprise one or more of:
yttrium oxyfluoride;
yttrium fluoride;
aluminum oxide;
magnesium oxide; or
yttrium oxide.

18. The substrate processing chamber of claim 15, wherein the polymer sealant comprises a first portion and a second portion, wherein a distance between the surface of the metal body and the first portion of the polymer sealant is smaller than the distance between the surface of the metal body and the second portion of the polymer sealant, and wherein a concentration of particles disposed within the polymer sealant is greater in the second portion of the polymer sealant than the first portion of the polymer sealant.

19. The substrate processing chamber of claim 15, wherein the component comprises:
a process chamber liner;
a slit door liner;
a plasma screen;
a cathode sleeve; or
a showerhead.

20. The substrate processing chamber of claim 15, wherein the plurality of particles have diameters between 10 and 500 nm.
